(19) United States
(12) Patent Application Publication
(10) Pub. No.: US 2026/0362854 A1
(43) Pub. Date: Nov. 12, 2026

(54) RED SEMICONDUCTOR LIGHT-EMITTING DEVICE FOR DISPLAY PIXELS, AND DISPLAY APPARATUS COMPRISING SAME

(71) Applicant: LG ELECTRONICS INC., Seoul (KR)

(72) Inventors: Donghun KANG, Seoul (KR); Jina JEON, Seoul (KR); Hyosang YU, Seoul (KR); Hyungjo PARK, Seoul (KR); Daesung KANG, Seoul (KR); Hajong BONG, Seoul (KR); Junseok SEONG, Seoul (KR)

(73) Assignee: LG ELECTRONICS INC., Seoul (KR)

(21) Appl. No.: 19/118,651

(22) PCT Filed: Oct. 5, 2023
(86) PCT No.: PCT/KR2023/015293

§ 371 Date: Apr. 4, 2025

(30) Foreign Application Priority Data
Oct. 5, 2022 (KR) 10-2022-0127094

(51) Int. Cl. H10H 20/812; H10H 20/824

(52) U.S. Cl. CPC H10H 20/812; H10H 20/824

(57) ABSTRACT

The embodiment relates to a red semiconductor light emitting device for a display pixel and a display device including the same.

The red semiconductor light emitting device for a display pixel according to the embodiment may include a first semiconductor light emitting structure including a first semiconductor layer of first conductivity type, a first active layer on the first semiconductor layer of first conductivity type, and a second semiconductor of second conductivity type layer on the first active layer, and a second semiconductor light emitting structure including a tunnel junction structure on the first semiconductor light emitting structure, a third semiconductor layer of first conductivity type disposed on the tunnel junction structure, a second active layer on the third semiconductor layer of first conductivity type, and a fourth semiconductor layer of second conductivity type on the second active layer.

The tunnel junction structure includes a first tunnel junction layer of second conductivity type disposed on the second semiconductor of second conductivity type layer; and may include a second tunnel junction layer of first conductivity type disposed on the first tunnel junction layer of second conductivity type.

### TECHNICAL FIELD

The embodiment relates to a red semiconductor light emitting device for display pixel and a display device including same.

### BACKGROUND ART

Large-area displays include liquid crystal displays (LCDs), OLED displays, and micro-LED displays.

A micro-LED display is a display that uses a micro-LED, a semiconductor light emitting device having a diameter or cross-sectional area of 100um or less, as a display element.

Since a micro-LED display uses a micro-LED, a semiconductor light emitting device, as a display element, it has excellent performance in many characteristics such as contrast ratio, response speed, color reproducibility, viewing angle, brightness, resolution, lifespan, luminous efficiency, or luminance.

In particular, a micro-LED display has the advantage of being able to freely adjust the size or resolution by separating and combining the screen in a modular manner, and the advantage of being able to implement a flexible display.

However, since large micro-LED displays require millions or more micro-LEDs, there is a technical problem in quickly and accurately transferring micro-LEDs to the display panel.

Transfer technologies that are being developed recently include the pick and place process, the laser lift-off method, or the self-assembly method.

Among these, the self-assembly method is a method in which semiconductor light emitting devices find their own assembly positions in a fluid, which is advantageous for implementing large-screen display devices.

Recently, U.S. Pat. No. 9,825,202 and others have presented micro-LED structures suitable for self-assembly, but research on technologies for manufacturing displays through self-assembly of micro-LEDs is still insufficient.

In particular, in the case of rapidly transferring millions or more semiconductor light emitting devices to a large display in the prior art, the transfer speed may be improved, but there is a technical problem that the transfer error rate may increase, which lowers the transfer yield.

In related technology, a self-assembly transfer process using dielectrophoresis (DEP) is being attempted, but there is a problem that the self-assembly rate is low due to the non-uniformity of the DEP force.

Meanwhile, according to a non-public internal technology, self-assembly of red (R) micro LED chips, green (G) micro LED chips, and blue (B) LED chips using DEP force is being studied.

Meanwhile, the micro Red LED chip has a decrease in chip efficiency due to non-light emission from the side.

In particular, the Red chip has a high carrier leakage at low initial current due to its fast mobility compared to the Blue and Green chips, which causes a decrease in chip brightness.

The low brightness of these Red chips causes problems of increased power consumption and decreased color reproducibility of the micro LED.

### DISCLOSURE

### Technical Problem

One of the technical problems of the embodiment is to provide a red semiconductor light emitting device for a display pixel and a display device including the same that improves brightness without causing problems of increased power consumption or decreased color reproducibility.

### Technical Solution

A red semiconductor light emitting device for a display pixel according to an embodiment may include a first semiconductor light emitting structure (251) including a first semiconductor layer of first conductivity type (251n), a first active layer (251a) on the first semiconductor layer of first conductivity type (251n), and a second semiconductor of second conductivity type layer (251p) on the first active layer (251a), a tunnel junction structure (250T1) on the first semiconductor light emitting structure (251), a third semiconductor layer of first conductivity type (252n) disposed on the tunnel junction structure (250T1), and a second semiconductor light emitting structure (252) including a second active layer (252a) on the third semiconductor layer of first conductivity type (252n) and a fourth semiconductor layer of second conductivity type (252p) on the second active layer (252a).

The tunnel junction structure (250T1) may include a first tunnel junction layer of second conductivity type (250Tp) disposed on the second semiconductor of second conductivity type layer (251p); and a second tunnel junction layer of first conductivity type (250Tn) disposed on the first tunnel junction layer of second conductivity type (250Tp).

The first tunnel junction layer of second conductivity type (250Tp) may include a p-type AlGaAs layer doped at a concentration of 1×10¹⁹ atoms/cm³ or more.

The second tunnel junction layer of first conductivity type (250Tn) may include an n-type GaInP layer doped at a concentration of 1×10¹⁹ atoms/cm³ or more.

The tunnel junction structure (250T2) may further include a third tunnel junction layer of second conductivity type (250Tp2) disposed below the first tunnel junction layer of second conductivity type (250Tp).

The third tunnel junction layer of second conductivity type (250Tp2) may include a p-type GaAs layer doped with a concentration of 1×10¹⁹ atoms/cm³ or more.

The first semiconductor light emitting structure (251B) may further include a fifth semiconductor layer of second conductivity type (265) disposed between the second semiconductor of second conductivity type layer (251p) and the tunnel junction structure (250T2).

The fifth semiconductor layer of second conductivity type (265) may include a p-(AlₓGa₁₋ₓ)_{y}In_{1-y}P layer (provided that 0.0≤x≤0.8, 0.2≤y≤0.6).

The first semiconductor light emitting structure (251B) may further include a sixth semiconductor layer of second conductivity type (266) disposed between the tunnel junction structure (250T1, 250T2) and the fifth semiconductor layer of second conductivity type (265).

The sixth semiconductor layer of second conductivity type (266) includes a p-(Alₓ₁Ga₁₋ₓ₁)_{y}In_{1-y}P layer (provided that 0.0≤x1≤0.8, 0.2≤y≤0.6), and the composition of Al in the sixth semiconductor layer of second conductivity type (266) may be graded.

The composition (X1) of Al of the second conductivity type sixth semiconductor layer (266) may be graded from 0.3~0.6 to 0.0 in the direction of the tunnel junction structure (250T1, 250T2).

The display device according to the embodiment may include any one of the red semiconductor light emitting devices for display pixels.

### Advantageous Effects

According to the red semiconductor light emitting device for display pixels according to the embodiment and the display device including the same, there is a technical feature that high brightness can be realized by including a first semiconductor light emitting structure (251), a second semiconductor light emitting structure (252), and a first or second tunnel junction structure (250T1, 250T2) disposed between the first and second semiconductor light emitting structures (251, 252), thereby enabling red wavelength light emission from two active layers.

In addition, according to the embodiment, while obtaining the same brightness increase effect as applying two red semiconductor light emitting devices, there is an effect of improving the power consumption of the LED display by 11.2% or more.

In addition, the red semiconductor light emitting device (250B) according to the second embodiment may include a fifth semiconductor layer of second conductivity type (265) between the first or second tunnel junction structure (250T1, 250T2) and the second semiconductor of second conductivity type layer (251p) of the first-second semiconductor light emitting structure (251B), and there is a special technical effect of improving the electrical problem of the hole barrier (HB) that occurs when a hole moving through the tunnel junction does not move smoothly due to an electrical barrier generated in the heterojunction region.

In addition, the red semiconductor light emitting device (250C) according to the third embodiment may include a sixth semiconductor layer of second conductivity type (266) between the first or second tunnel junction structure (250T1, 250T2) and the second semiconductor of second conductivity type layer (251p) of the first-third semiconductor light emitting structure (251C).

According to the third embodiment, the composition of Al further includes the sixth semiconductor layer of second conductivity type (266) that is graded, thereby providing a special technical effect of further improving the electrical problem of the hole barrier (HB).

### DESCRIPTION OF DRAWINGS

FIG. 1 is an example drawing of a living room of a house in which a display device according to the embodiment is placed.

FIG. 2 is an enlarged view of the first panel area in the display device of FIG. 1.

FIG. 3 is a cross-sectional view along the line B1-B2 of the A2 area of FIG. 2.

FIG. 4 is an example of a light emitting device according to an embodiment being assembled on a substrate by a self-assembly method.

FIG. 5 is a partial enlarged view of the A3 area of FIG. 4.

FIG. 6 is a cross-sectional view of a red semiconductor light emitting device (250A) for a display pixel according to the first embodiment.

FIG. 7A is a schematic diagram of a first tunnel junction structure (250T1) according to the first embodiment.

FIG. 7B is a schematic diagram of a second tunnel junction structure (250T2) according to the first embodiment.

FIG. 8 is a conceptual diagram of an energy band diagram in a red semiconductor light emitting device of internal technology.

FIG. 9 is a partial cross-sectional schematic diagram of a red semiconductor light emitting device (250B) according to the second embodiment.

FIG. 10 is a partial cross-sectional schematic diagram of a red semiconductor light emitting device (250C) according to the third embodiment.

FIG. 11 is a cross-sectional view of a red semiconductor light emitting device (250D) according to the fifth embodiment.

### MODE FOR INVENTION

Hereinafter, the embodiments disclosed in the present specification will be described in detail with reference to the attached drawings. The suffixes ‘module’ and ‘part’ for components used in the following description are given or used interchangeably in consideration of the ease of writing the specification, and do not have distinct meanings or roles in themselves. In addition, the attached drawings are intended to facilitate easy understanding of the embodiments disclosed in the present specification, and the technical ideas disclosed in the present specification are not limited by the attached drawings. In addition, when an element such as a layer, a region, or a board is referred to as existing ‘on’ another component, this includes that it may be present directly on the other element or that other intermediate elements may exist in between.

The display device described in this specification may include a digital TV, a mobile phone, a smart phone, a laptop computer, a digital broadcasting terminal, a personal digital assistant (PDA), a portable multimedia player (PMP), a navigation, a slate PC, a tablet PC, an Ultra-Book, a desktop computer, etc. However, the configuration according to the embodiment described in this specification may also be applied to a device capable of displaying, even if it is a new product type developed in the future.

The following describes a semiconductor light emitting device according to an embodiment and a display device including the same.

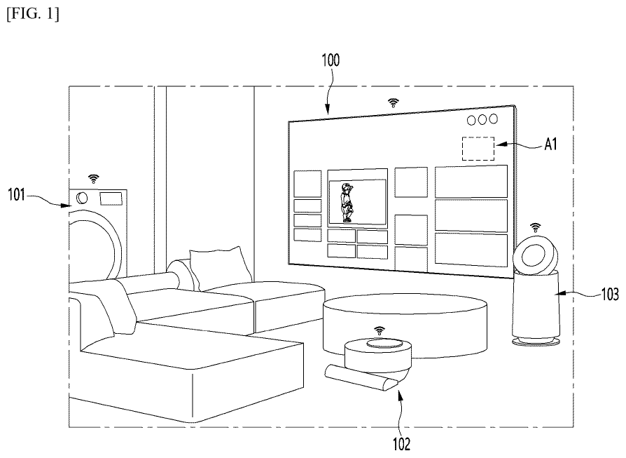

FIG. 1 illustrates a living room of a house in which a display device (100) according to an embodiment is disposed.

The display device (100) according to the embodiment may display the status of various electronic products such as a washing machine (101), a robot vacuum cleaner (102), and an air purifier (103), communicate with each electronic product based on IoT, and control each electronic product based on the user's setting data.

The display device (100) according to the embodiment may include a flexible display manufactured on a thin and flexible substrate. The flexible display may be bent or rolled like paper while maintaining the characteristics of a conventional flat panel display.

In the flexible display, visual information may be implemented by independently controlling the light emission of unit pixels disposed in a matrix form. A unit pixel means the minimum unit for implementing one color. The unit pixel of the flexible display may be implemented by a light emitting device. In the embodiment, the light emitting device may be a Micro-LED or a Nano-LED, but is not limited thereto.

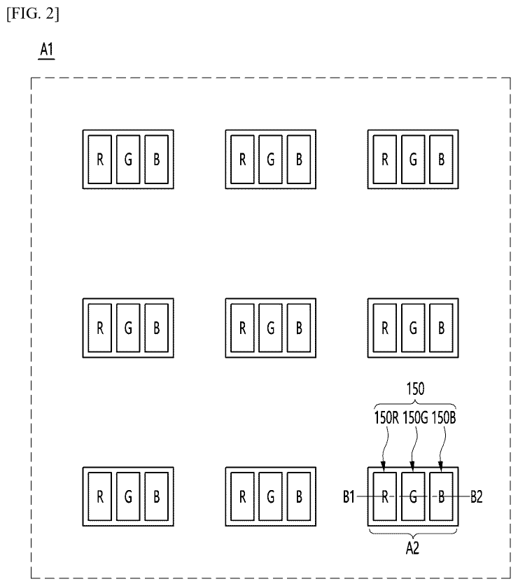

FIG. 2 is an enlarged view of the first panel area (A1) in the display device of FIG. 1.

According to FIG. 2, the display device (100) of the embodiment may be manufactured by mechanically and electrically connecting a plurality of panel areas such as the first panel area (A1) by tiling.

The first panel area (Al) may include a plurality of light emitting devices (150) disposed for each unit pixel.

For example, the unit pixel may include a first sub-pixel, a second sub-pixel, and a third sub-pixel. For example, a plurality of red light emitting devices (150R) may be disposed in the first sub-pixel, a plurality of green light emitting devices (150G) may be disposed in the second sub-pixel, and a plurality of blue light emitting devices (150B) may be disposed in the third sub-pixel. The unit pixel may further include a fourth sub-pixel in which no light emitting devices are disposed, but this is not limited thereto. Meanwhile, the light emitting device (150) may be a semiconductor light emitting device.

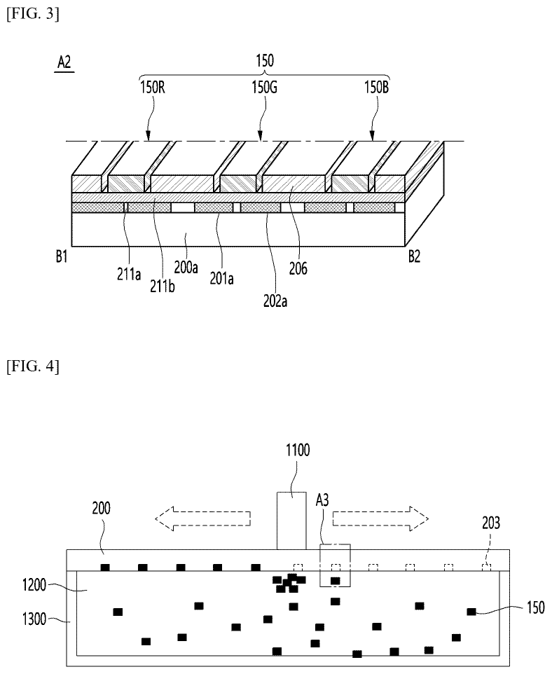

Next, FIG. 3 is a cross-sectional view taken along the line B1-B2 of the A2 region of FIG. 2.

Referring to FIG. 3, the display device (100) of the embodiment may include a substrate (200a), spaced wirings (201a, 202a), a first insulating layer (211a), a second insulating layer (211b), a third insulating layer (206), and a plurality of light emitting devices (150).

The wiring may include a first wiring (201a) and a second wiring (202a) spaced apart from each other. The first wiring (201a) and the second wiring (202a) may function as panel wiring for applying power to the light emitting device (150) in the panel, and in the case of self-assembly of the light emitting device (150), the wirings may also function as assembly electrodes for generating a dielectric force for assembly.

The wirings (201a, 202a) may be formed of a transparent electrode (ITO) or may include a metal material having excellent electrical conductivity. For example, the wiring (201a, 202a) may be formed of at least one of titanium (Ti), chromium (Cr), nickel (Ni), aluminum (Al), platinum (Pt), gold (Au), tungsten (W), molybdenum (Mo), or an alloy thereof.

A first insulating layer (211a) may be disposed between the first wiring (201a) and the second wiring (202a), and a second insulating layer (211b) may be disposed on the first wiring (201a) and the second wiring (202a). The first insulating layer (211a) and the second insulating layer (211b) may be an oxide film, a nitride film, or the like, but are not limited thereto.

The light emitting device (150) may include a red light emitting device (150R), a green light emitting device (150G), and a blue light emitting device (150B) to form a unit pixel (sub-pixel), but are not limited thereto, and may include a red fluorescent element and a green fluorescent element to implement red and green, respectively.

The substrate (200) may be formed of glass or polyimide. In addition, the substrate (200) may include a flexible material such as PEN (Polyethylene Naphthalate) or PET (Polyethylene Terephthalate). In addition, the substrate (200) may be a transparent material, but is not limited thereto. The substrate (200) may function as a support substrate in the panel, and may also function as an assembly substrate when self-assembling a light emitting device.

The third insulating layer (206) may include an insulating and flexible material such as polyimide, PEN, PET, etc., and may be formed integrally with the substrate (200) to form a single substrate.

The third insulating layer (206) may be a conductive adhesive layer having adhesiveness and conductivity, and the conductive adhesive layer may be flexible to enable a flexible function of the display device. For example, the third insulating layer (206) may be a conductive adhesive layer such as an anisotropic conductive film (ACF) or an anisotropic conductive medium, a solution containing conductive particles, etc. The conductive adhesive layer may be a layer that is electrically conductive in the vertical direction relative to the thickness, or electrically insulating in the horizontal direction relative to the thickness.

The gap between the wirings (201a, 202a) is formed smaller than the width of the light emitting device (150) and the width of the assembly hole (203), so that the assembly position of the light emitting device (150) using the electric field may be more precisely fixed.

A third insulating layer (206) is formed on the wirings (201a, 202a), so as to protect the wirings (201a, 202a) from the fluid (1200) and prevent leakage of current flowing through the wirings (201a, 202a). The third insulating layer (206) may be formed as a single layer or multiple layers of an inorganic insulator such as silica or alumina, or an organic insulator.

In addition, the third insulating layer (206) may include an insulating and flexible material such as polyimide, PEN, PET, etc., and may be formed integrally with the substrate (200) to form a single substrate.

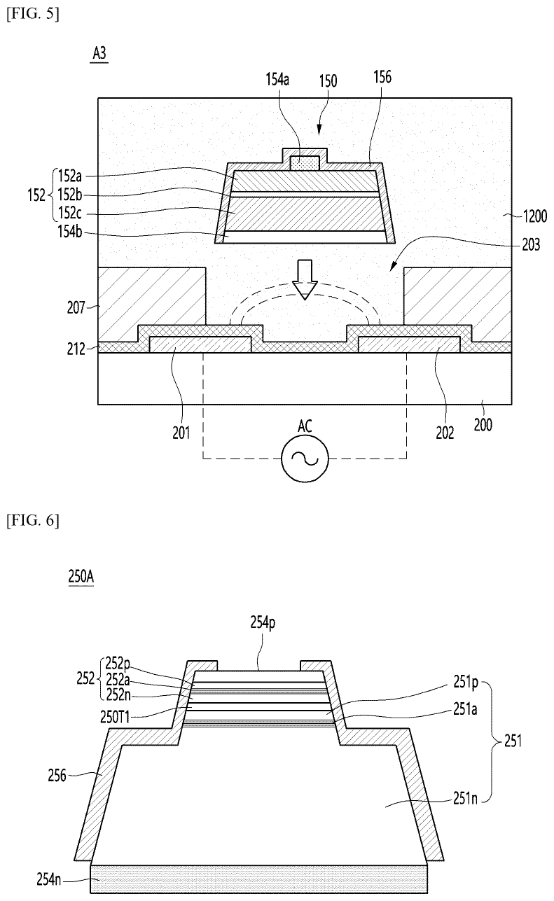

The third insulating layer (206) may have a partition, and an assembly hole (203) may be formed by the partition. For example, the third insulating layer (206) may include an assembly hole (203) for inserting a light emitting device (150) (see FIG. 5). Therefore, when self-assembling, the light emitting device (150) may be easily inserted into the assembly hole (203) of the third insulating layer (206). The assembly hole (203) may be called an insertion hole, a fixing hole, an alignment hole, etc.

The assembly hole (203) may have a shape and size corresponding to the shape of the light emitting device (150) to be assembled at the corresponding position. Accordingly, it is possible to prevent another light emitting device from being assembled in the assembly hole (203) or multiple light emitting devices from being assembled.

Next, FIG. 4 is a drawing showing an example in which a light emitting device according to an embodiment is assembled on a substrate by a self-assembly method, and FIG. 5 is a partial enlarged view of the A3 area of FIG. 4. FIG. 5 is a drawing in which the A3 area is rotated 180 degrees for convenience of explanation.

Based on FIG. 4 and FIG. 5, an example in which a semiconductor light emitting device according to an embodiment is assembled on a display panel by a self-assembly method using an electromagnetic field will be described.

The assembly substrate (200) described below may also function as a panel board in a display device after assembling a light emitting device, but the embodiment is not limited thereto.

Referring to FIG. 4, a semiconductor light emitting device (150) may be introduced into a chamber (1300) filled with a fluid (1200), and the semiconductor light emitting device (150) may be moved to the substrate (200) by a magnetic field generated from an assembly device (1100). At this time, the light emitting device (150) adjacent to the assembly hole (203) of the assembly substrate (200) may be assembled into the assembly hole (230) by a dielectrophoretic force caused by the electric field of the assembly electrodes. The fluid (1200) may be water such as ultrapure water, but is not limited thereto. The chamber may be called a tank, a container, a vessel, etc.

After the semiconductor light emitting device (150) is introduced into the chamber (1300), the assembly substrate (200) may be placed on the chamber (1300). Depending on the embodiment, the assembly substrate (200) may also be introduced into the chamber (1300).

Referring to FIG. 5, the semiconductor light emitting device (150) may be implemented as a vertical semiconductor light emitting device as shown, but is not limited thereto, and a horizontal light emitting device may be employed.

The semiconductor light emitting device (150) may include a magnetic layer (not shown) having a magnetic material. The magnetic layer may include a metal having magnetism, such as nickel (Ni). Since the semiconductor light emitting device (150) injected into the fluid includes a magnetic layer, it may move to the substrate (200) by a magnetic field generated from the assembly device (1100). The magnetic layer may be disposed on the upper side, lower side, or both sides of the light emitting device.

The semiconductor light emitting device (150) may include a passivation layer (156) surrounding the upper surface and side surfaces. The passivation layer (156) may include an inorganic insulator, such as silica or alumina, may be formed through PECVD, LPCVD, sputtering deposition, etc. In addition, the passivation layer (156) may be formed through a method of spin coating an organic material such as a photoresist or a polymer material.

The semiconductor light emitting device (150) may include a first conductivity type semiconductor layer (152a), a second conductivity type semiconductor layer (152c), and an active layer (152b) disposed therebetween. The first conductivity type semiconductor layer (152a) may be an n-type semiconductor layer, and the second conductivity type semiconductor layer (152c) may be a p-type semiconductor layer, but is not limited thereto.

The semiconductor light emitting device (150) illustrated in FIG. 5 may be a blue semiconductor light emitting device (150B) or a green semiconductor light emitting device (150G), but is not limited thereto.

A first electrode may be connected to the first conductivity type semiconductor layer (152a), and a second electrode may be connected to the second conductivity type semiconductor layer (152c). To this end, some areas of the first conductivity type semiconductor layer (152a) and the second conductivity type semiconductor layer (152c) may be exposed to the outside. Accordingly, after the semiconductor light emitting device (150) is assembled on the assembly substrate (200), some areas of the passivation layer (156) may be etched in the manufacturing process of the display device.

The assembly substrate (200) may include a pair of first assembly electrodes (201) and second assembly electrodes (202) corresponding to each of the semiconductor light emitting devices (150) to be assembled. The first assembly electrodes (201) and second assembly electrodes (202) may be formed by multiply stacking a single metal, a metal alloy, a metal oxide, etc.

The first assembly electrode (201) and the second assembly electrode (202) may fix the semiconductor light emitting device (150) inserted into the assembly hole (203) by the dielectric force by emitting an electric field when an AC voltage is applied. The gap between the first assembly electrode (201) and the second assembly electrode (202) may be smaller than the width of the semiconductor light emitting device (150) and the width of the assembly hole (203), and the assembly position of the semiconductor light emitting device (150) may be fixed more precisely using the electric field.

An insulating layer (212) is formed on the first assembly electrode (201) and the second assembly electrode (202), thereby protecting the first assembly electrode (201) and the second assembly electrode (202) from the fluid (1200) and preventing leakage of current flowing through the first assembly electrode (201) and the second assembly electrode (202). For example, the insulating layer (212) may be formed as a single layer or multiple layers of an inorganic insulator such as silica or alumina, or an organic insulator. The insulating layer (212) may have a minimum thickness to prevent damage to the first assembly electrode (201) and the second assembly electrode (202) when assembling the semiconductor light emitting device (150), and may have a maximum thickness to stably assemble the semiconductor light emitting device (150).

A partition wall (207) may be formed on the upper portion of the insulating layer (212). Some areas of the partition wall (207) may be located on the upper portion of the first assembly electrode (201) and the second assembly electrode (202), and the remaining areas may be located on the upper portion of the assembly substrate (200).

Meanwhile, when manufacturing the assembly substrate (200), some of the partition walls formed over the entire upper portion of the insulating layer (212) are removed, so that an assembly hole (203) may be formed in which each of the semiconductor light emitting devices (150) is coupled and assembled to the assembly substrate (200).

An assembly hole (203) in which the semiconductor light emitting devices (150) are coupled is formed in the assembly substrate (200), and a surface on which the assembly hole (203) is formed may come into contact with a fluid (1200). The assembly hole (203) may guide the exact assembly position of the semiconductor light emitting device (150).

Meanwhile, the assembly hole (203) may have a shape and size corresponding to the shape of the semiconductor light emitting device (150) to be assembled at the corresponding position. Accordingly, it is possible to prevent another semiconductor light emitting device from being assembled in the assembly hole (203) or a plurality of semiconductor light emitting devices from being assembled.

Referring back to FIG. 4, after the assembly substrate (200) is placed in the chamber, an assembly device (1100) that applies a magnetic field may move along the assembly substrate (200). The assembly device (1100) may be a permanent magnet or an electromagnet.

The assembly device (1100) may move in contact with the assembly substrate (200) to maximize the area affected by the magnetic field into the fluid (1200). Depending on the embodiment, the assembly device (1100) may include a plurality of magnetic bodies or may include magnetic bodies of a size corresponding to the assembly substrate (200). In this case, the movement distance of the assembly device (1100) may be limited to a predetermined range.

The semiconductor light emitting device (150) in the chamber (1300) may move toward the assembly device (1100) and the assembly substrate (200) by the magnetic field generated by the assembly device (1100).

Referring to FIG. 5, the semiconductor light emitting device (150) may be fixed by entering the assembly hole (203) by the dielectrophoretic force (DEP force) formed by the electric field of the assembly electrode of the assembly substrate while moving toward the assembly device (1100).

Specifically, the assembly wiring (201, 202) forms an electric field by the AC power, and the dielectrophoretic force may be formed between the assembly wiring (201, 202) by this electric field. The semiconductor light emitting device (150) may be fixed to the assembly hole (203) on the substrate (200) by this dielectrophoretic force.

At this time, a predetermined solder layer (not shown) may be formed between the light emitting device (150) assembled on the assembly hole (203) of the substrate (200) and the assembly electrode to improve the bonding strength of the light emitting device (150).

In addition, a molding layer (not shown) may be formed on the assembly hole (203) of the assembly substrate (200) after assembly. The molding layer may be a transparent resin or a resin containing a reflective material or a scattering material.

By the self-assembly method using the electromagnetic field described above, the time required for each semiconductor light emitting device to be assembled on the substrate may be drastically shortened, so that a large-area, high-pixel display may be implemented more quickly and economically.

Next, FIG. 6 is a cross-sectional view of a red semiconductor light emitting device (250A) for a display pixel according to the first embodiment. Hereinafter, “red semiconductor light emitting device for display pixel” will be abbreviated as “red semiconductor light emitting device.”

The red semiconductor light emitting device (250A) according to the first embodiment may include a first semiconductor light emitting structure (251), a second semiconductor light emitting structure (252), and a first tunnel junction structure (250T1) disposed between the first and second semiconductor light emitting structures (251, 252).

The red semiconductor light emitting device (250A) according to the first embodiment may include a first electrode layer (254n) disposed below the first semiconductor light emitting structure (251) and a second electrode layer (254p) disposed above the second semiconductor light emitting structure (252).

The first electrode layer (254n) may include a metal having magnetism, such as nickel (Ni). The second electrode layer (254p) may include a light-transmitting ohmic layer such as ITO, but is not limited thereto.

The red semiconductor light emitting device (250A) according to the first embodiment may include a passivation layer (256) including an inorganic insulator such as silica or alumina, which is disposed on the upper surface and the side surface.

The red semiconductor light emitting device (250A) according to the first embodiment may be an AlGaInP-based light emitting diode, and may emit light with a wavelength within a range of about 570 nm to about 630 nm. The wavelength may be determined by the band gap energy of the light emitting diode. For example, the band gap size may be controlled by changing the composition ratio of Al and Ga, and the wavelength may become shorter as the composition ratio of Al increases.

In the first embodiment, the first semiconductor light emitting structure (251) may include a first semiconductor layer of first conductivity type (251n), a first active layer (251a) on the first semiconductor layer of first conductivity type (251n), and a second semiconductor of second conductivity type layer (251p) on the first active layer (251a).

The first semiconductor light emitting structure (251) may include a (AlₓGa₁₋ₓ)_{y}In_{1-y}P layer (provided that 0.0≤x≤1.0, 0.01≤y≤0.9), and the first semiconductor layer of first conductivity type (251n) may be doped with an N-type dopant, and the second semiconductor of second conductivity type layer (251p) may be doped with a P-type dopant, but is not limited thereto.

For example, the N-type dopant may be Si or Te, etc., and the P-type dopant may be Mg or C (carbon), but is not limited thereto.

The first semiconductor layer of first conductivity type (251n) may include a high-concentration first conductive first-first semiconductor layer (not shown) and a low-concentration first conductive first-second semiconductor layer (not shown), but is not limited thereto.

For example, the first conductive first-first semiconductor layer may include an n−-AlGaInP layer, and the first conductive first-second semiconductor layer may include an n-GaP layer, but is not limited thereto.

In addition, in the first embodiment, the second semiconductor light emitting structure (252) may include a third semiconductor layer of first conductivity type (252n), a second active layer (252a) on the third semiconductor layer of first conductivity type (252n), and a fourth semiconductor layer of second conductivity type (252p) on the second active layer (252a).

The second semiconductor light emitting structure (252) may include a (AlₓGa₁₋ₓ)_{y}In_{1-y}P layer (provided that 0.0≤x≤1.0, 0.01≤y≤0.9), and the third semiconductor layer of first conductivity type (252n) may be doped with an N-type dopant, and the fourth semiconductor layer of second conductivity type (252p) may be doped with a P-type dopant, but is not limited thereto. For example, the N-type dopant may be Si or Te, etc., and the P-type dopant may be Mg or C (carbon), but is not limited thereto.

In addition, the second conductivity type fourth semiconductor layer (252p) comprises a low-concentration second conductivity type fourth-first semiconductor layer (not shown) and a high-concentration second conductivity type fourth-second semiconductor layer (not shown), but is not limited to.

For example, the fourth-first semiconductor layer may include a p-AlGalnP layer, and the fourth-second semiconductor layer may include, but is not limited to, a p+-GaP layer.

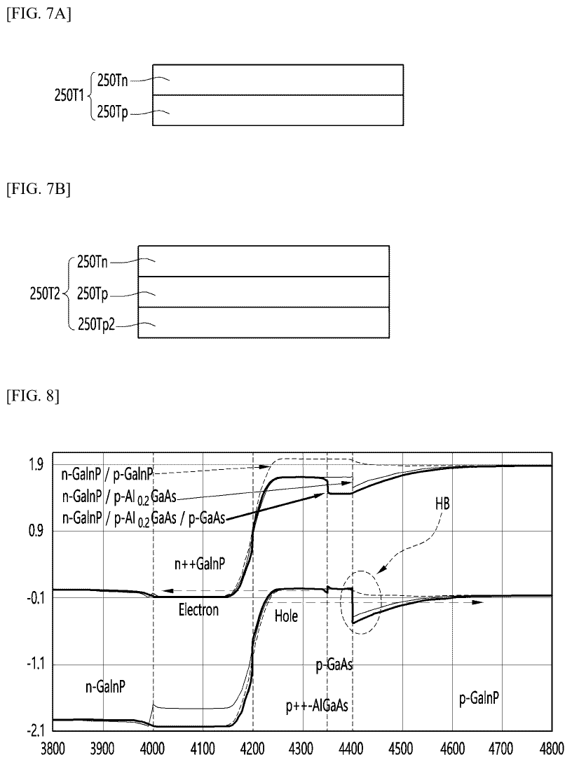

FIG. 7A is a schematic diagram of the first tunnel junction structure (250T1) of the first embodiment.

The first tunnel junction structure (250T1) of the first embodiment may be doped at a high concentration of 1×10¹⁹ atoms/cm³ or more.

The first tunnel junction structure (250T1) of the first embodiment may include a first tunnel junction layer of second conductivity type (250Tp) and a second tunnel junction layer of first conductivity type (250Tn).

The first tunnel junction layer of second conductivity type (250Tp) may include a high-concentration AlGaAs layer.

For example, the first tunnel junction layer of second conductivity type (250Tp) may include a p++-AlGaAs layer doped with carbon (C) at a high concentration of 1×10¹⁹ atoms/cm³ or more.

Next, the second tunnel junction layer of first conductivity type (250Tn) may include a high-concentration GaInP layer. For example, the second tunnel junction layer of first conductivity type (250Tn) may include an n++-GaInP layer doped with Si at a high concentration of 1×10¹⁹ atoms/cm³ or more.

FIG. 7B is a schematic diagram of the second tunnel junction structure (250T2) of the first embodiment.

The second tunnel junction structure (250T2) of the first embodiment may include a first tunnel junction layer of second conductivity type (250Tp), a second tunnel junction layer of first conductivity type (250Tn), and a third tunnel junction layer of second conductivity type (250Tp2). The third tunnel junction layer of second conductivity type (250Tp2) may be disposed under the first tunnel junction layer of second conductivity type (250Tp).

The third tunnel junction layer of second conductivity type (250Tp2) may include a high-concentration GaAs layer. For example, the third tunnel junction layer of second conductivity type (250Tp2) may include a p++-GaAs layer doped with carbon (C) at a high concentration of 1×10¹⁹ atoms/cm³ or more.

According to an embodiment, there is a technical feature that high brightness can be realized by including a first semiconductor light emitting structure (251), a second semiconductor light emitting structure (252), and a first or a second tunnel junction structure (250T1, 250T2) disposed between the first and second semiconductor light emitting structures (251, 252), thereby enabling red wavelength light emission from two active layers.

In addition, according to an embodiment, while obtaining a brightness increase effect equivalent to applying two red semiconductor light emitting devices, there is an effect of improving the power consumption of the LED display by 11.2% or more (based on full white, 300 nit).

FIG. 8 is a conceptual diagram of an energy band diagram in a red semiconductor light emitting device of internal technology.

According to the red semiconductor light emitting device of the internal technology, it was studied that a hole barrier (HB) exists between the first semiconductor light emitting structure (251) and the first or second tunnel junction structure (250T1, 250T2).

For example, a hole barrier (HB) may exist between the first or second tunnel junction structure (250T1, 250T2) and the p-type clad layer, which is the second semiconductor of second conductivity type layer (251p) of the first semiconductor light emitting structure (251).

For example, it was studied that a hole barrier (HB) may exist due to an offset caused by a difference in bandgap energy and a difference in Fermi level of the heterogeneous materials between the first or second tunnel junction structure (250T1, 250T2) requiring high concentration doping and the p-type clad layer, which is the second semiconductor of second conductivity type layer (251p) of the first semiconductor light emitting structure (251).

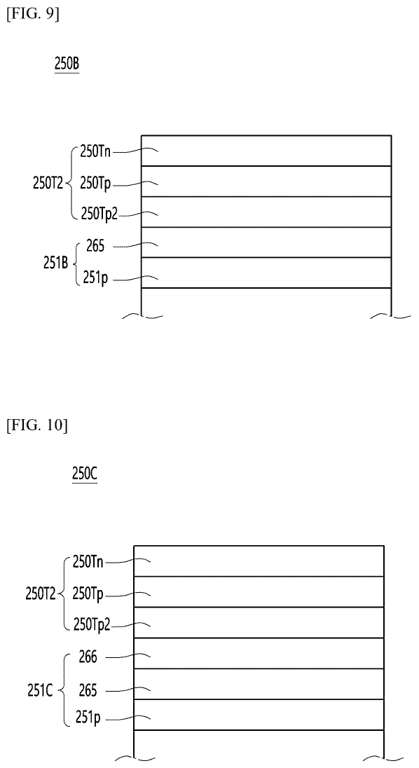

FIG. 9 is a partial cross-sectional schematic diagram of a red semiconductor light emitting device (250B) according to the second embodiment.

The red semiconductor light emitting device (250B) according to the second embodiment may adopt the technical features of the red semiconductor light emitting device (250A) according to the first embodiment.

For example, the red semiconductor light emitting device (250B) according to the second embodiment may include a first tunnel junction structure (250T1) or a second tunnel junction structure (250T2).

Hereinafter, the technical features of the red semiconductor light emitting device (250B) according to the second embodiment will be described.

The red semiconductor light emitting device (250B) according to the second embodiment may include a fifth semiconductor layer of second conductivity type (265) between the first or second tunnel junction structure (250T1, 250T2) and the second semiconductor of second conductivity type layer (251p) of the first-second semiconductor light emitting structure (251B).

The second conductivity type fifth semiconductor layer (265) may include a p-(AlₓGa₁₋ₓ)_{y}In_{1-y}P layer (provided that 0.0≤x≤0.8, 0.2≤y≤0.6), and may be doped with Mg, but is not limited thereto.

In general, when a Phosphide series AlInP series layer growing as a cladding layer in an LED structure is joined with an Arsenide series AlGaAs series layer forming a tunnel junction, a heterojunction is formed in terms of material, but since the lattice constant difference between the materials may be controlled by controlling the Al composition of the two layers, it is common to grow them continuously without inserting a separate Interlayer layer between the joining layers.

Meanwhile, as shown in FIG. 8, although the epi growth itself does not cause a problem in the p-AlInP/AlGaAs junction despite being a junction of different materials, it has been studied that a hole barrier (HB) exists between the first semiconductor light emitting structure (251) and the first or second tunnel junction structure (250T1, 250T2) according to the red semiconductor light emitting device of the internal technology.

For example, it has been studied that a hole barrier (HB) may exist due to an offset occurring due to the difference in bandgap energy and the difference in Fermi level of the different materials between the first or second tunnel junction structure (250T1, 250T2) requiring high concentration doping and the second semiconductor of second conductivity type layer (251p) of the first semiconductor light emitting structure (251).

The red semiconductor light emitting device (250B) according to the second embodiment may include a fifth semiconductor layer of second conductivity type (265) between the first or second tunnel junction structure (250T1, 250T2) and the second semiconductor of second conductivity type layer (251p) of the first-second semiconductor light emitting structure (251B),

and the second embodiment has a special technical effect of improving the electrical problem of the hole barrier (HB) that occurs when a hole moving through the tunnel junction may not move smoothly due to an electrical barrier generated in the heterojunction region.

In the field of LED technology, the p-AlInP/AlGaAs junction is a junction of heterogeneous materials, but the epi growth itself does not cause problems, and since the AlGaAs/AlInP heterojunction in the field of LED technology is a junction grown without an interlayer, it is not easy to notice that an electrical problem is occurring in the corresponding junction layer.

Next, FIG. 10 is a partial cross-sectional schematic diagram of a red semiconductor light emitting device (250C) according to the third embodiment.

The red semiconductor light emitting device (250C) according to the third embodiment may adopt the technical features of the red semiconductor light emitting devices (250A, 250B) according to the first or second embodiment.

For example, the red semiconductor light emitting device (250C) according to the third embodiment may include a first tunnel junction structure (250T1) or a second tunnel junction structure (250T2).

Hereinafter, the technical features of the red semiconductor light emitting device (250C) according to the third embodiment will be described.

The red semiconductor light emitting device (250C) according to the third embodiment may include a fifth semiconductor layer of second conductivity type (265) and a sixth semiconductor layer of second conductivity type (266) between the first or second tunnel junction structure (250T1, 250T2) and the second semiconductor of second conductivity type layer (251p) of the first-third semiconductor light emitting structure (251C).

The fifth semiconductor layer of second conductivity type (265) may include a p-(AlₓGa₁₋ₓ)_{y}In_{1-y}P layer (provided that 0.0≤x<0.8, 0.2≤y≤0.6), and may be doped with Mg, but is not limited thereto.

In addition, the sixth semiconductor layer of second conductivity type (266) may include a p-(Alₓ₁Ga₁₋ₓ₁)_{y}In_{1-y}P layer (wherein 0.0≤x1≤0.8, 0.2≤y≤0.6) and may be doped with Mg, but is not limited thereto.

The composition of Al in the sixth semiconductor layer of second conductivity type (266) may be graded.

For example, the composition X1 of Al in the sixth semiconductor layer of second conductivity type (266) may be graded from 0.3~0.6 to 0.0.

The red semiconductor light emitting device (250C) according to the third embodiment may include a sixth semiconductor layer of second conductivity type (266) between the first or second tunnel junction structure (250T1, 250T2) and the second semiconductor of second conductivity type layer (251p) of the first-third semiconductor light emitting structure (251C).

According to the third embodiment, the composition of Al further includes a graded sixth semiconductor layer of second conductivity type (266), thereby providing a special technical effect of further improving the electrical problem of the hole barrier (HB).

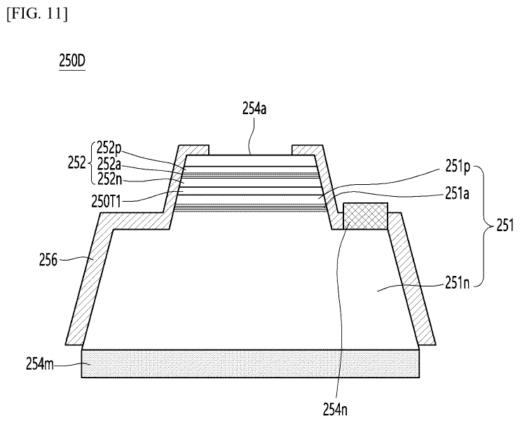

FIG. 11 is a cross-sectional view of the red semiconductor light emitting device (250d) according to the fifth embodiment.

The red semiconductor light emitting device (250D) according to the fifth embodiment may adopt the technical features of the red semiconductor light emitting device (250A) for display pixels according to the first embodiment illustrated in FIG. 6.

Unlike the first embodiment, the red semiconductor light emitting device (250D) according to the fifth embodiment may include a horizontal semiconductor light emitting device structure.

For example, according to the fifth embodiment, the red semiconductor light emitting device (250D) may have a first electrode layer (254) electrically connected to an upper portion of the first semiconductor layer of first conductivity type (251n). The fifth embodiment may further include a magnetic layer (254m) disposed below the first semiconductor light emitting structure (251).

According to the red semiconductor light emitting device for display pixels according to the embodiment and the display device including the same, there is a technical feature that high brightness can be realized by including the first semiconductor light emitting structure (251), the second semiconductor light emitting structure (252), and the first or the second tunnel junction structure (250T1, 250T2) disposed between the first and second semiconductor light emitting structures (251, 252), thereby enabling red wavelength light emission from two active layers.

In addition, according to the embodiment, while obtaining the same brightness increase effect as applying two red semiconductor light emitting devices, there is an effect of improving the power consumption of the LED display by 11.2% or more.

In addition, the red semiconductor light emitting device (250B) according to the second embodiment may include a fifth semiconductor layer of second conductivity type (265) between the first or second tunnel junction structure (250T1, 250T2) and the second semiconductor of second conductivity type layer (251p) of the first-second semiconductor light emitting structure (251B), and there is a special technical effect of improving the electrical problem of the hole barrier (HB) that occurs when a hole moving through the tunnel junction does not move smoothly due to an electrical barrier generated in a heterojunction region.

In addition, the red semiconductor light emitting device (250C) according to the third embodiment may include a sixth semiconductor layer of second conductivity type (266) between the first or second tunnel junction structure (250T1, 250T2) and the second semiconductor of second conductivity type layer (251p) of the first-third semiconductor light emitting structure (251C).

According to the third embodiment, the composition of Al further includes the sixth semiconductor layer of second conductivity type (266) that is graded, thereby providing a special technical effect of further improving the electrical problem of the hole barrier (HB).

The detailed description should not be construed as limiting in all aspects and should be considered as illustrative. The scope of the embodiments should be determined by a reasonable interpretation of the appended claims, and all changes within the equivalent scope of the embodiments are included in the scope of the embodiments.

### INDUSTRIAL APPLICABILITY

The embodiments may be adopted in the field of displays that display images or information.

The embodiment may be adopted in the field of displays that display images or information using semiconductor light emitting devices.

The embodiment may be adopted in the field of displays that display images or information using micro-level or nano-level semiconductor light emitting devices.

1. A red semiconductor light emitting device for a display pixel, comprising:
a first semiconductor light emitting structure including a first semiconductor layer of first conductivity type, a first active layer on the first semiconductor layer of first conductivity type, and a second semiconductor of second conductivity type layer on the first active layer,
a tunnel junction structure on the first semiconductor light emitting structure; and
a second semiconductor light emitting structure including a third semiconductor layer of first conductivity type disposed on the tunnel junction structure, a second active layer on the third semiconductor layer of first conductivity type, and a fourth semiconductor layer of second conductivity type on the second active layer,
wherein the tunnel junction structure comprises:
a first tunnel junction layer of second conductivity type disposed on the second semiconductor of second conductivity type layer; and
a second tunnel junction layer of first conductivity type disposed on the first tunnel junction layer of second conductivity type.

2. The red semiconductor light emitting device for the display pixel according to claim 1, wherein the first tunnel junction layer of second conductivity type comprises a p-type AlGaAs layer doped with a concentration of 1×10¹⁹ atoms/cm³ or more.

3. The red semiconductor light emitting device for the display pixel according to claim 1, wherein the second tunnel junction layer of first conductivity type comprises an n-type GaInP layer doped with a concentration of 1×10¹⁹ atoms/cm³ or more.

4. The red semiconductor light emitting device for the display pixel according to claim 1, wherein the tunnel junction structure further comprises a third tunnel junction layer of second conductivity type disposed below the first tunnel junction layer of second conductivity type.

5. The red semiconductor light emitting device for the display pixel according to claim 4, wherein the third tunnel junction layer of second conductivity type comprises a p-type GaAs layer doped with a concentration of 1×10¹⁹ atoms/cm³ or more.

6. The red semiconductor light emitting device for the display pixel according to claim 1, wherein the first semiconductor light emitting structure further comprises a fifth semiconductor layer of second conductivity type disposed between the second semiconductor of second conductivity type layer and the tunnel junction structure.

7. The red semiconductor light emitting device for the display pixel according to claim 6, wherein the fifth semiconductor layer of second conductivity type comprises a p-(AlₓGa₁₋ₓ)_{y}In_{1-y}P layer (0.05x<0.8, 0.25y≤0.6).

8. The red semiconductor light emitting device for the display pixel according to claim 6, wherein the first semiconductor light emitting structure further comprises a sixth semiconductor layer of second conductivity type disposed between the tunnel junction structure and the fifth semiconductor layer of second conductivity type.

9. The red semiconductor light emitting device for the display pixel according to claim 8, wherein the sixth semiconductor layer of second conductivity type includes a p-(Alₓ₁Ga₁₋ₓ₁)_{y}In_{1-y}P layer (provided that 0.0≤x1≤0.8 and 0.2≤y≤0.6), and the composition of Al in the sixth semiconductor layer of second conductivity type is graded.

10. The red semiconductor light emitting device for the display pixel according to claim 9, wherein the composition (X1) of Al in the sixth semiconductor layer of second conductivity type is graded from 0.3~0.6 to 0.0 in the direction of the tunnel junction structure.

11. A display device including the red semiconductor light emitting device for the display pixel according to claim 1.

12. The red semiconductor light emitting device for the display pixel according to claim 6, wherein the tunnel junction structure further includes a third tunnel junction layer of second conductivity type disposed below the first tunnel junction layer of second conductivity type, and
wherein the fifth semiconductor layer of second conductivity type is disposed between the second semiconductor layer of second conductivity type and the third tunnel junction layer of second conductivity type.

13. The red semiconductor light emitting device for the display pixel according to claim 8, wherein the tunnel junction structure further includes a third tunnel junction layer of second conductivity type disposed below the first tunnel junction layer of second conductivity type,
and the sixth semiconductor layer of second conductivity type is disposed between the second semiconductor layer of second conductivity type and the third tunnel junction layer of second conductivity type.

14. The red semiconductor light emitting device for the display pixel according to claim 13, wherein the sixth semiconductor layer of second conductivity type is disposed between the fifth semiconductor layer of second conductivity type and the third tunnel junction layer of second conductivity type.

15. The red semiconductor light emitting device for the display pixel according to claim 1, wherein the first conductivity type semiconductor layer includes a first concentration first conductive first-first semiconductor layer and a first conductive first-second semiconductor layer having a second concentration lower than the first concentration.

16. The red semiconductor light emitting device for the display pixel according to claim 15, wherein the first conductivity type first-first semiconductor layer includes an n+-AlGaInP layer,
and the first conductivity type first-second semiconductor layer includes an n-GaP layer, a red semiconductor light-emitting element for a display pixel.
